(19) United States
(12) Patent Application Publication
(10) Pub. No.: US 2011/0195187 A1
(43) Pub. Date: Aug. 11, 2011

(54) DIRECT LIQUID VAPORIZATION FOR OLEOPHOBIC COATINGS

(75) Inventors: Douglas Joseph Weber, Arcadia, CA (US); Naoto Matsuyuki, Nagoya (JP)

(73) Assignee: APPLE INC., Cupertino, CA (US)

(21) Appl. No.: 13/024,964

(22) Filed: Feb. 10, 2011

Related U.S. Application Data
(60) Provisional application No. 61/303,089, filed on Feb. 10, 2010.

(51) Int. Cl. C23C 16/448; C23C 16/52; B05D 5/00

(52) U.S. Cl. 427/248.1; 118/726; 118/715; 118/698

(57) ABSTRACT

This is directed to a liquid vaporization process for depositing an oleophobic ingredient on a surface of an electronic device component using a PVD process. A raw liquid material that includes the oleophobic ingredient can be placed in a liquid supply system coupled to a vacuum chamber. The liquid supply system can be pressured by an inert gas to prevent undesired chemical reactions between the oleophobic ingredient and air. The liquid, including the oleophobic ingredient, can vaporize upon reaching the vaporizing unit, and the oleophobic ingredient can be deposited on the component.

### CROSS-REFERENCE TO RELATED APPLICATION

This application claims the benefit of Provisional U.S. Patent Application No. 61/303,089, filed on Feb. 10, 2010, titled “Direct Liquid Vaporization for Oleophobic Coatings,” which is hereby incorporated by reference herein in its entirety.

### BACKGROUND

This is directed to applying an oleophobic coating to the surface of a material. In particular, this is directed to using a direct liquid application in a Physical Vapor Deposition (“PVD”) chamber to apply the coating to the material.

An electronic device can include a surface on which a user can provide inputs. For example, an electronic device can include a touch sensitive surface that a user can touch to provide inputs to the device. The touch sensitive surface can be incorporated as any suitable part of the device including, for example, a track pad, a keyboard, a display, or combinations of these. As the user touches the surface, however, oils and other particles from the user's fingers can be deposited on the surface. This may adversely affect the appearance of the surface, especially if information is being displayed on the surface (e.g., when the surface is the top layer of the exterior of a display).

One way to limit the amount of oils and particles deposited on the surface is to apply an oleophobic treatment to the surface. The treatment can include any suitable material having oleophobic properties. For example, an active oleophobic ingredient can be incorporated into pellets, which can be placed in a vacuum chamber with the materials to be coated. When heat is applied, the oleophobic ingredient can be vaporized. The vaporized material can then be deposited on the surface of the materials placed within the vacuum chamber.

This approach, however, can be difficult to accomplish. For example, it can be hard to control the quality of the oleophobic material when the pellets are generated. In particular, the oleophobic material can be contaminated by exposure to air and moisture when it is initially placed in a tank or disbursed by a dispenser to form the pellets. In addition, it is possible that heating the material prior to vaporization may negatively affect its oleophobic performance.

### SUMMARY

This is directed to using a direct liquid deposition process to apply an oleophobic coating to an electronic device surface.

To prevent the deposition of oils on an electronic device surface, an oleophobic ingredient can be bonded to the electronic device surface. The oleophobic ingredient can be provided as part of a raw liquid material in one or more concentrations. To avoid adverse reactions due to exposure to air, heat, or humidity, the raw liquid material can be placed in a bottle purged with an inert gas.

The bottle can be placed in a liquid supply system having a mechanism for controlling the amount of raw liquid material that passes through the liquid supply system. Upon reaching the vaporizing unit, the liquid can be vaporized and the oleophobic ingredient within the liquid can then be deposited on the electronic device component surface. As the liquid supply is drained from the bottle, additional inert gas is supplied in its place to further prevent contamination.

### BRIEF DESCRIPTION OF THE DRAWINGS

The above and other features of the present invention, its nature and various advantages will be more apparent upon consideration of the following detailed description, taken in conjunction with the accompanying drawings in which:

FIG. 1 shows a perspective view of an electronic device on which an oleophobic surface treatment is applied in accordance with embodiments of the invention;

FIG. 2 is a schematic view of an illustrative system for applying an oleophobic material in liquid form on a device surface in accordance with embodiments of the invention;

FIG. 3A is a schematic view of an illustrative liquid supply system in accordance with embodiments of the invention;

FIG. 3B is a schematic view of an illustrative liquid supply system in accordance with embodiments of the invention;

FIG. 4 is a perspective view of an illustrative apparatus for applying an oleophobic material in liquid form on a device surface in accordance with embodiments of the invention;

FIG. 5 is a schematic view of an illustrative system for applying an oleophobic material in liquid form on a device surface in accordance with embodiments of the invention;

FIG. 6A shows a schematic view of a batch liquid physical vapor deposition system containing one apparatus for applying an oleophobic material in accordance with embodiments of the invention;

FIG. 6B shows a schematic view of a batch liquid physical vapor deposition system containing more than one apparatus for applying an oleophobic material in accordance with embodiments of the invention;

FIG. 7 shows a schematic view of an inline liquid physical vapor deposition system in accordance with embodiments of the invention; and

FIG. 8 is a flow chart of a process for depositing oleophobic material on a device surface in accordance with embodiments of the invention.

### DETAILED DESCRIPTION

An electronic device can include a surface that may be responsive to a user's touch to provide inputs to the device. In some cases, the touched surface of the device can also be used as a display. Sometimes, however, when the user touches the surface oils or other particles can be deposited on the surface that may interfere with the user's ability to view the display. For example, as a result of various inputs, the display surface can include numerous smudges and fingerprints that can make it more difficult to view what is being displayed. One or more treatments, such as the deposition of an oleophobic material, for example, can be applied to the surface to prevent, or at least reduce, the oils or particles from being deposited on the surface.

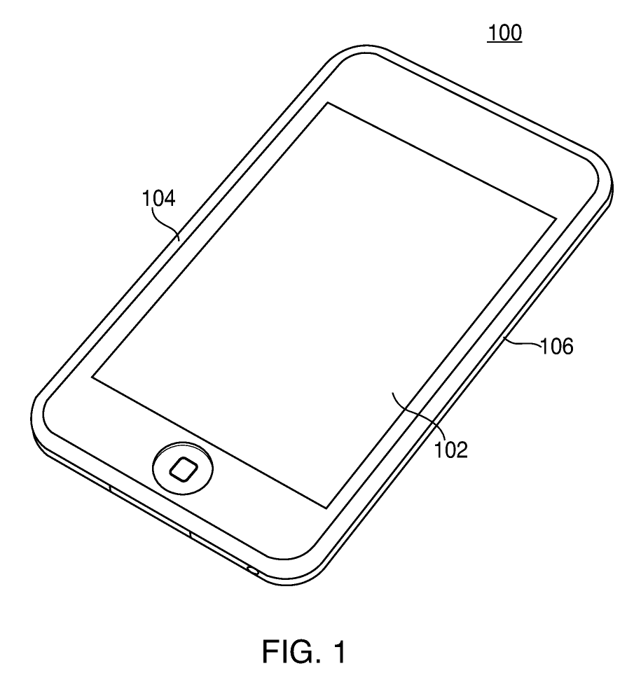

FIG. 1 is a schematic view of an electronic device on which an oleophobic surface treatment can be applied in accordance with embodiments of the invention. Electronic device 100 can include housing 102, bezel 104 and window 106. Bezel 104 can be coupled to housing 102 in a manner that secures window 106 to bezel 104. Housing 102 and bezel 104 can be constructed from any suitable materials including, for example, plastic, metal, or a composite material. In at least one implementation, housing 102 can be constructed from plastic or any metal such as aluminum, and bezel 104 can be constructed from any metal, such as stainless steel. Window 106 can be constructed from any suitable transparent or translucent material including, for example, glass or plastic. Different electronic device elements can be retained within electronic device 100 to provide functionality to the user. For example, a touch sensitive surface can be incorporated in or behind window 106 such that a user can provide inputs to electronic device 100 by manipulating virtual objects displayed on window 106 while viewing content displayed through the window.

An oleophobic treatment can be applied to one or more surfaces or components of electronic device 100 (e.g., to window 106) using more than one approach. In some embodiments the oleophobic material can be deposited on the surface of window 106 from a pellet that includes the active oleophobic ingredient diluted in a liquid dilutant. The oleophobic ingredient in the liquid can be sensitive to heat, humidity, and air. Excess exposure to these elements, alone or in combination, may cause the raw liquid material to lose its oleophobic properties. In particular, the oleophobic ingredient can react chemically in the presence of heat or humidity and lose its ability to later chemically react with the surface (e.g., the glass particles that make up window 106). Alternatively, the chemical molecule of the oleophobic ingredient can be modified (e.g., a carbon chain can be split). In traditional PVD systems it is difficult to limit the exposure of the oleophobic material to the harmful elements listed above. For example, the exposure of the oleophobic ingredient to air may result in difficulty applying the oleophobic ingredient directly to a device surface in a PVD chamber.

The raw liquid material may be obtained by mixing the oleophobic ingredient with any suitable dilutant. For example, one or more of HFE, PFE, or any other suitable dilutant known in the art, can be used to dilute the oleophobic ingredient. The dilutant may be selected based on any suitable approach. For example, the dilutant (and concentration of the oleophobic ingredient) can be selected to reduce the susceptibility of the oleophobic ingredient to one or more environmental triggers to ensure that the ingredient remains active during and after transit. As another example, the dilutant can be selected to provide a raw liquid material having a desired viscosity. In particular, the oleophobic ingredient can be highly viscous and may require a dilutant to allow the oleophobic ingredient to fully vaporize during the PVD process. The oleophobic ingredient can have any suitable concentration in the raw liquid material including, for example, a concentration in the range of 10% to 100% (e.g., 20% or 50%).

To ensure that the oleophobic material can be properly deposited on a surface of the electronic device without exposing the material to air, the raw liquid material containing the oleophobic material can be used to manufacture a pellet that includes substantially only the oleophobic material to be deposited on the device surface.

The raw liquid material can be poured into a tank filled with inert gas (e.g., argon or nitrogen). By using an inert gas instead of air, for example, the process can reduce or limit the exposure of the active ingredient to triggers that may cause its effectiveness to decrease. Using the inert gas to pressurize the tank, the liquid can be passed through a pump at a uniform rate and density and directed to a dispenser. The dispenser can then dispense the pressurized liquid into a pellet cup.

A pellet cup can be a cup constructed from a material having high thermal conductivity to ensure that heat can conduct through the cup to the material within the cup and a porous material placed within the cup. The pellet cup can include any suitable porous material including, for example, steel wool. When the raw liquid material is dispensed into the pellet cup, it permeates the porous material within the cup. The cup can then be heated (e.g., in an oven) such that the dilutant part of the raw liquid material evaporates. This process results in leaving only the oleophobic ingredient within the porous material thus a solid pellet of the oleophobic ingredient is formed.

The amount of oleophobic ingredient contained by the pellet can be determined from the concentration of the oleophobic ingredient in the raw liquid material and the volume of the raw liquid material dispensed into the cup. In some embodiments, each pellet can have an amount of oleophobic ingredient in the range of 40-200 mg (e.g., 80 mg or 160 mg). Alternatively, several pellets having lesser amounts of the oleophobic ingredient (e.g., two pellets each having 80 mg) can be placed together within the PVD chamber to provide sufficient quantities of the ingredient to coat a batch of electronic device components. For example, the PVD chamber may have a 2 m diameter and hold approximately 300 individual glass windows. In some embodiments, the amount of oleophobic ingredient placed in the chamber can exceed the minimum amount necessary to prevent oil deposits on the surface, as higher densities of the oleophobic ingredient may have other beneficial properties such as enhancing the abrasion resistance of the component.

To apply the oleophobic ingredient to the electronic device surface, one or more pellets can be placed within a PVD chamber along with the electronic device surface. For example, one or more pellets can be placed within a vacuum chamber in which a fixture holds one or more electronic device components defining external surfaces of the device (e.g., glass window components). In one implementation, two pellets can be used to coat approximately 300 glass components. To extract the oleophobic ingredient from the pellets, the pellets are heated. For example, the conductive cup can be placed on a resistive heating element such that heat generated by the heating element is thermally conducted through the cup to the porous material and the oleophobic ingredient.

In reaction to the heat, the oleophobic ingredient will vaporize and form a cloud within the PVD chamber. The cloud can disperse throughout the chamber and coat the surfaces of the electronic device components placed within the chamber. The oleophobic ingredient can create one or more chemical bonds with the surface of the electronic device elements (e.g., with glass molecules) to adhere securely to the surface. In some embodiments, one or more additional process steps (e.g., exposure to air, heat, or humidity) can be introduced after deposition of the oleophobic coating to improve the quality of the bond between the oleophobic ingredient and the surface as well as other properties of the oleophobic coating.

This pellet-based approach, however, can have some limitations. In particular, adjusting the amount of oleophobic ingredient provided to components within the PVD chamber can require extensive lead time for generating new pellets having the desired concentrations of the oleophobic ingredient. An alternative approach can be to provide the raw liquid material directly to the PVD chamber in liquid form.

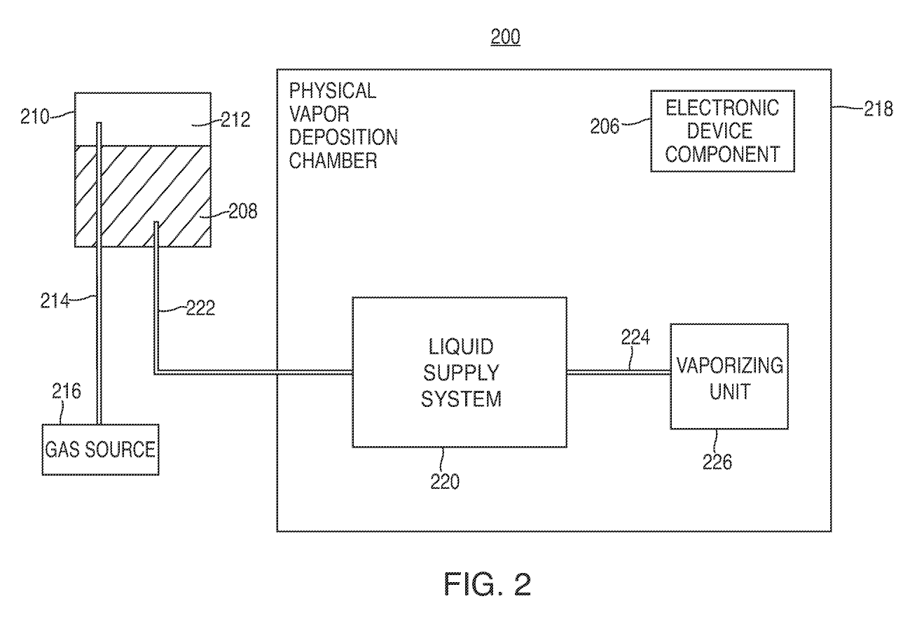

FIG. 2 is a schematic view of an illustrative process for liquid vaporization of an oleophobic ingredient in accordance with embodiments of the invention. System 200 can include raw liquid material 208 placed in pressurized bottle 210 purged with inert gas 212 (e.g., argon or nitrogen), which is supplied by gas source 216 through hose or pipe 214. The particular gas used can be selected to reduce or eliminate exposure of the oleophobic ingredient to triggers that may adversely affect the ingredient (e.g., air, heat, and humidity). In some embodiments, raw liquid material 208 can be placed within pressurized bottle 210 and inert gas 212 can be inserted to flush air out of pressurized bottle 210. Pressurized bottle 210 can be coupled directly to PVD vacuum chamber 218 by first tube section 222 as part of liquid supply system 220. This approach can ensure that raw liquid material 208, and thus the oleophobic ingredient, is not exposed to air once it is placed within pressurized bottle 210. Liquid supply system 220 can include any suitable combination of tubes, pumps, and valves, including tube section 222, for directing raw liquid material 208 into the vaporizing unit 226 for vaporization. The vaporized oleophobic ingredient can then be deposited onto one or more electronic device components 206. Electronic device components 206 may be any suitable components, including a number of windows 106 (described above in description FIG. 1).

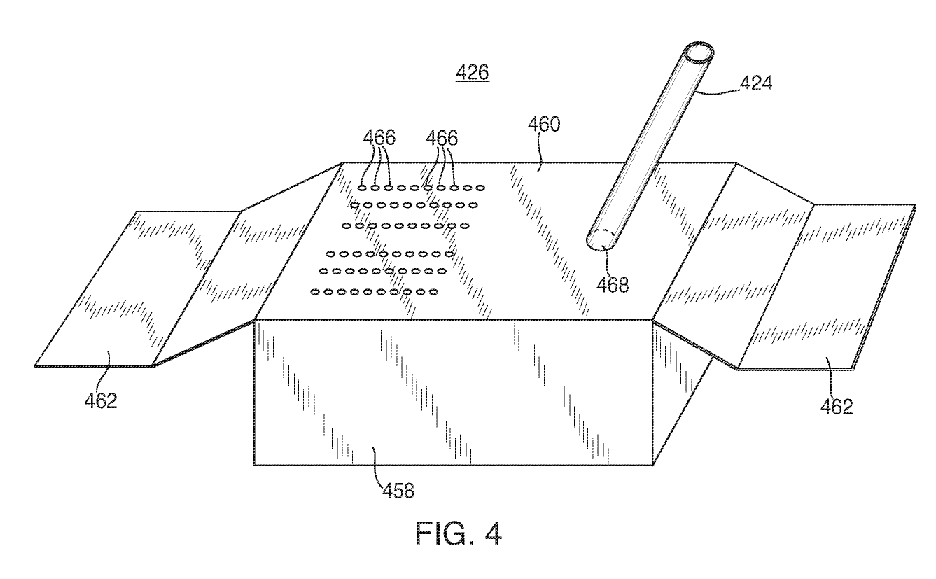

Vaporizing unit 226 can be cold, warm, or hot when liquid supply system 220 provides raw liquid material 208. For example, raw liquid material 208 can be provided on a cold or warm vaporizing unit 226 which is then heated to vaporize raw liquid material 208. Alternatively, raw liquid material 208 can be provided to a hot unit. Any suitable vaporizing unit 226 can be used including, for example, vaporizing unit 426 (which is described in more detail below in connection with FIG. 4), a copper cup, porous ceramic, steel wool, heat resistant material, material with a high thermal conductivity, or combinations of these.

Using liquid vaporization system 200 can provide several advantages over a pellet based system. In some embodiments, liquid supply system 220 can be adjusted so that the amount of material (e.g., an oleophobic ingredient) deposited on components 206 placed within PVD chamber 218 can be varied in a controlled manner. For example, liquid supply system 220 can be adjusted based on the number of electronic device components 206 placed within the chamber 218. Furthermore, the amount of the oleophobic ingredient provided can be adjusted very quickly. In contrast, a pellet-based approach can require the manufacture of new pellets having specific amounts of oleophobic material, which can require more lead time (e.g., a few days, as opposed to minutes or hours) and is more likely to result in contamination.

Raw liquid material 208 used in system 200 can have any suitable concentration of oleophobic ingredient. For example, the oleophobic ingredient concentration can be in the range of 10% to 100%. In particular, pure or substantially pure oleophobic ingredient (i.e., with little or no dilutant) can be used because the viscosity of the ingredient may not matter when passing it directly into PVD chamber 218.

In some embodiments, one or more of heat, humidity, and air can be applied to the coated electronic device components 206 after deposition to ensure that the chemical reaction between the oleophobic ingredient and device components 206 has completed. In the liquid vaporization approach, one or more chemicals can be applied to the components within or outside PVD chamber 218 to ensure that the chemical reaction is complete. One or more other wet processes may be incorporated with the oleophobic treatment (e.g., using the same or different liquid supply systems within the PVD chamber 218).

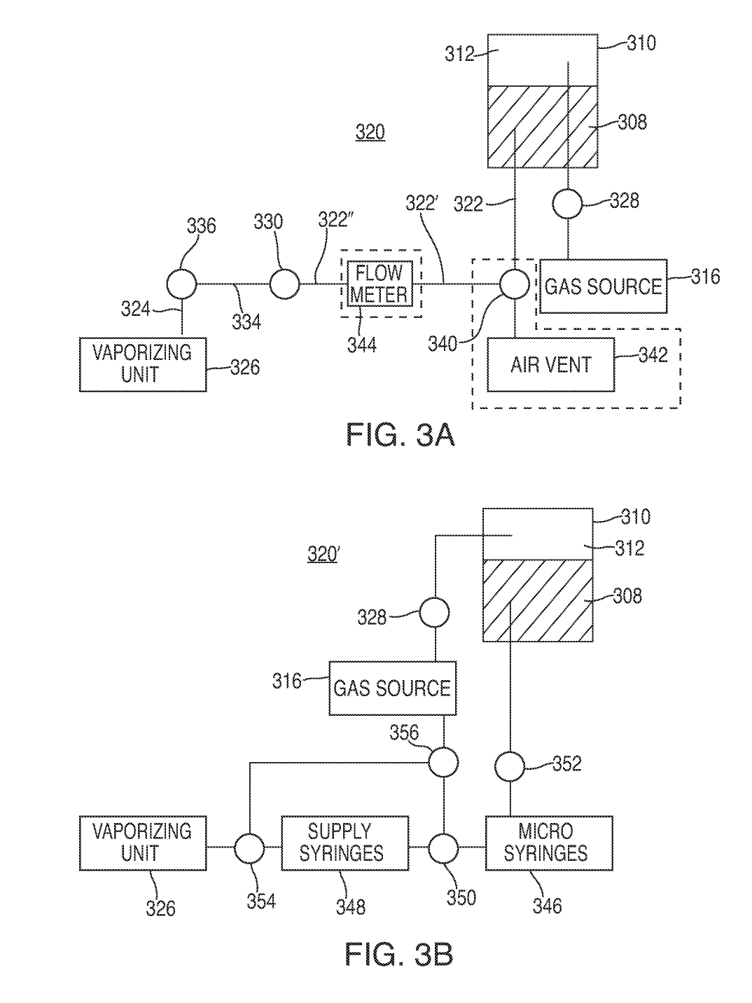

FIG. 3A is a schematic view of liquid supply system 320 that can be incorporated to work with a PVD chamber (e.g., the PVD chamber 218) in accordance with embodiments of the invention. For example, liquid supply system 320 can correspond to liquid supply system 220 (shown in FIG. 2). Liquid supply system 320 can incorporate pressurized bottle 310, which can contain raw liquid material 308. Pressurized bottle 310 can be coupled to inert gas source 316 (e.g., an argon gas line) to provide back pressure to liquid supply system 320 such that only inert gas 312 is placed in contact with raw liquid material 308 (and, therefore, the oleophobic ingredient). Flow of inert gas 312 from inert gas source 316 may be controlled by gas valve 328.

First valve 330 can be opened to allow raw liquid material 308 to flow from first tube section 322 into second tube section 334. (In embodiments of the liquid supply system 320 that include air vent 342 and flow meter 344, both of which are described in more detail below, first tube section 322 may be separated into three distinct sections 322, 322′ and 322″. If only one of those elements is present, the first tube section may be separated into two separate sections, 322 and 322′.) First and second tube sections (322 and 334, respectively) can be made of any suitable material (e.g., stainless steel). The volume of second tube section 334 may be optimized to provide a specific amount of raw liquid material 308 to vaporizing unit 326. First valve 330 may be closed when the second tube section 334 is filled with raw liquid material 308. Second valve 336 may then be opened to allow the raw liquid material 308 to flow from second tube section 334 to vaporizing unit 326 through supply tube 324. Because supply tube 324 can come in contact with the vaporizing unit 326, it may need to be designed to withstand high temperature. Supply tube 324 can consist of any suitable material for such conditions (e.g., a carbon material or a ceramic material).

Liquid supply system 320 depicted in FIG. 3A may have several advantages over a pellet based deposition system. The fixed volume available in second tube section 334 ensures consistent delivery of a predetermined amount, or “shot”, of raw liquid material 308 to vaporizing unit 326. Therefore, for a given concentration of the oleophobic material in raw liquid material 308, liquid supply system 320 can deliver a consistent amount of the oleophobic ingredient each time the process is run. This approach can provide a reliable way to deliver substantially uniform coatings to a large number of components consistently over time. Moreover, the amount of the oleophobic ingredient used for a particular process run can be adjusted very easily by either adjusting the volume of second tube section 334 or the concentration of the oleophobic ingredient in raw liquid material 308.

A third valve 340 may be introduced into liquid supply system 320. Third valve 340 may be coupled to first tube section 322 (i.e., between tube sections 322 and 322′) and air vent 342. Air vent 342 may be used to purge tube sections 322, 322′, 334, and 324 (and 322″ if applicable) of air, when necessary. For example, air may flow into tube sections 322, 322′, 334, and 324 (and 322″ if applicable) when pressurized bottle 310 holding raw liquid material 308 and inert gas 312 is changed (e.g., when there is no raw liquid material 308 left in the bottle). Third valve 340 and air vent 342 may prevent new raw liquid material 308 from coming in contact with air, which can decrease the effectiveness of the oleophobic ingredient.

Liquid supply system 320 may also be equipped with flow meter 344 interposed between third valve 340 and first valve 330. Flow meter 344 may be used to determine when second tube section 334 is full. For example, when first valve 330 is opened, flow meter 344 can detect the rate at which raw liquid material 308 is flowing through first tube section 322. By measuring the flow rate, flow meter 344 can help determine whether second tube section 334 is full. For example, when first valve 330 is open and second valve 336 is closed, raw liquid material 308 will flow into second tube section 334 until second tube section 334 is filled. When second tube section 334 is filled, flow meter 344 can detect that the flow has stopped. At that time, the amount of raw liquid material 308 that has passed through flow meter 344 may be compared to an expected value. If the two values match, second tube section 334 is filled with the predetermined amount and the shot is ready for vaporization. If the two values do not match, flow meter 344 can report the problem, which may be, for example, a blockage in liquid supply system 320.

FIG. 3B is a schematic view of liquid supply system 320′ that can be incorporated to work with a PVD chamber (such as PVD chamber 218 described above) in accordance with embodiments of the invention. Liquid supply system 320′ can incorporate pressurized bottle 310 of raw liquid material 308. Pressurized bottle 310 can be connected to previously described gas source 316 (e.g., an argon gas line) to provide back pressure to liquid supply system 320′ such that only inert gas 312 is placed in contact with raw liquid material 308 (and, therefore, the oleophobic ingredient). Inert gas 312 can also provide pressure to direct raw liquid material 308 out of pressurized bottle 310 and into one or more micro syringes 346 and supply syringes 348. Micro syringes 346 can provide a precise and uniform flow of raw liquid material 308 out and into supply syringes 348. Micro syringes 346 can be selected or controlled to output any suitable amount of raw liquid material 308. In some embodiments, inert gas 312 provided by gas source 316 can be used to provide back pressure to move the raw liquid material through micro syringes 346.

Micro syringe 346 can direct raw liquid material 308 to supply syringes 348, which can be operative to disperse raw liquid material 308 into vaporizing unit 326. In some embodiments, micro syringes 346 can direct a specific measured amount of raw liquid material 308 into supply syringes 348. For example, for each batch of electronic device components placed in the vacuum chamber (not shown for simplicity), micro syringes 346 can direct a predetermined amount of raw liquid material 308 into supply syringes 348. Once the shot of raw liquid material 308 has been provided to supply syringes 348, valves 390 and 392 can be closed. Using micro syringes 346 can help ensure that a consistent amount of the raw liquid material 308 is placed within vaporizing unit 326 for each batch of electronic device components.

Supply syringes 348 can discharge the raw liquid material 308 provided by micro syringes 346 using any suitable approach. For example, inert gas 312 (e.g., argon or nitrogen) from gas source 316 can be used to force the raw liquid material 308 out of supply syringes 348. In some embodiments, supply syringes 348 can include a valve or nozzle 394 for directing the liquid towards vaporizing unit 326 within the vacuum chamber. For example, supply syringes 348 can provide raw liquid material 308 to vaporizing unit 326 as droplets or as a spray (e.g., a spray having one or more streams). Upon reaching vaporizing unit 326, raw liquid material 308 can be heated to allow the oleophobic ingredient to vaporize and be deposited on the electronic device components placed within the chamber.

FIG. 4 shows a perspective view of an illustrative vaporizing unit 426. Vaporizing unit 426 may be used, for example, in place of vaporizing unit 226 (FIG. 2) or 326 (FIGS. 3A and 3B) to provide further advantages of embodiments disclosed herein. Vaporizing unit 426 may include vessel 458, cover 460, tabs 462, and supply tube 424. In some embodiments, cover 460 may have a number of holes 466 through which raw liquid material may escape in vapor form. Cover 460 may also include an aperture 468 operable to allow vessel 458 to receive raw liquid material from a liquid supply system (previously described, but not shown for simplicity).

Vaporizing unit 426 can be heated by any suitable means in order to cause raw liquid material to become vaporized. For example, in some embodiments, a resistive heating unit (not shown for simplicity) may be coupled to tabs 462. Vaporizing unit 426 may be made of any suitable material operable to withstand high temperatures and allow the efficient transfer of heat to the raw liquid material (e.g., a refractory metal such as molybdenum). Similarly, because supply tube 424 will be in contact with vaporizing unit 426, it should be made of a heat resistant material (e.g., a carbon or ceramic material) sufficient to withstand the elevated temperatures that will be applied to vaporizing unit 426.

Cover 460, while not necessarily required, may prevent the raw liquid material from splattering within the PVD chamber as well as provide other advantages. In some embodiments, the PVD chamber can be under a high vacuum when the liquid supply system delivers raw liquid material to vaporizing unit 426. If the pressure within the PVD chamber is lower than the vapor pressure of the dilutant in the raw liquid material, the dilutant may boil away immediately upon entering vaporizing unit 426. Cover 460 may, therefore, be further useful to prevent the dilutant from splattering within the PVD chamber in those circumstances. Holes 466 can provide an outlet for the vaporized dilutant to exit vaporizing unit 426 before it is removed from the PVD chamber through an exhaust unit (not shown for clarity).

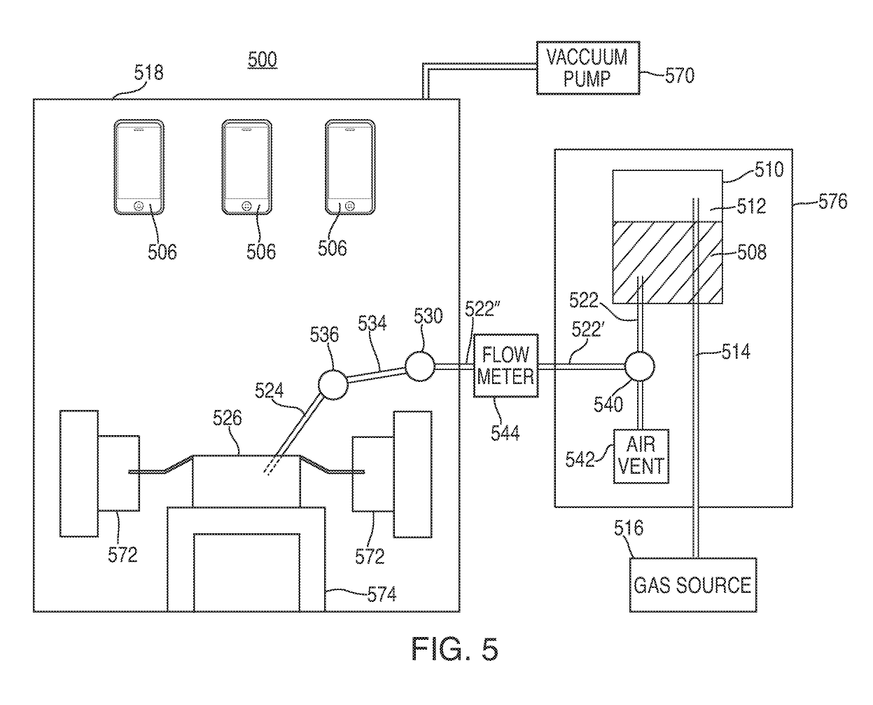

FIG. 5 is a schematic of a system for direct liquid vaporization of an oleophobic coating 500 according to embodiments of the invention. System 500 includes PVD vacuum chamber 518. Vacuum pump 570 may be operable to reduce the pressure within PVD vacuum chamber 518 up to, or beyond, two optimal levels. A number of electronic device components 506 may be mounted inside of the PVD vacuum chamber 518. Also inside of the PVD vacuum chamber 518, resistive heating units 572 can be coupled to vaporizing unit 526. The system may include table 574 to support the vaporizing unit 526. Additionally, supply tube 524 (similar to supply tube section 424 described above) can couple vaporizing unit 526 to a liquid supply system that may include of a set of tube sections, valves, syringes, or other suitable components.

The liquid supply system as depicted in FIG. 5, according to embodiments of the invention, is situated mostly within PVD vacuum chamber 518. However, one can appreciate that a liquid supply system may, for example, be situated fully inside of PVD vacuum chamber 518, be fully outside of PVD vacuum chamber 518, or have components both inside and outside of PVD vacuum chamber 518. For example, the liquid supply system can include first valve 530, second valve 536, first tube section 522, second tube section 534, third valve 540, air vent 542, and flow meter 544.

The liquid supply system can be coupled by first tube section 522, to pressurized bottle 510, which may contain, for example, raw liquid material 508 and inert gas 512 (e.g., argon or nitrogen). Inert gas 512 can be supplied through hose or pipe 514 by gas source 516. Refrigerator 576 may be included in system 500 to keep the contents of pressurized bottle 510 within a desirable temperature and/or humidity range. The usable life span of raw liquid material 508 may be extended if it is kept in, for example, a cool and dry environment.

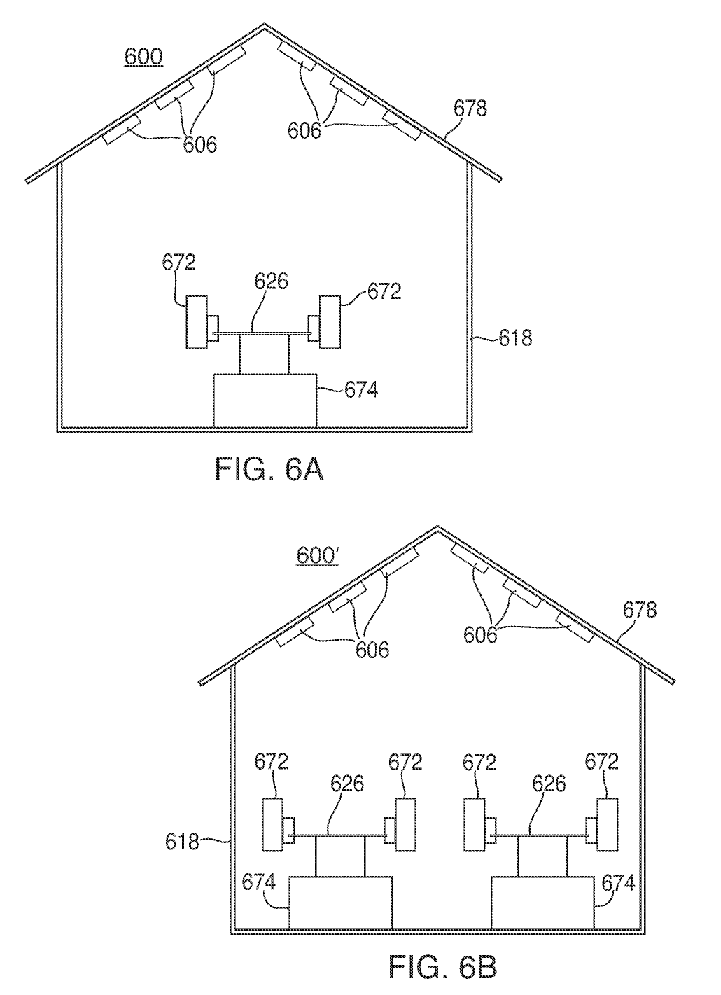

FIG. 6A shows a cross-sectional schematic view of batch liquid PVD system 600 according to embodiments of the invention. System 600 may include PVD vacuum chamber 618, rotating pallet 678, electronic device components 606 mounted to rotating pallet 678, vaporizing unit 626, and resistive heating unit 672. The system may also include table 674 operable to support vaporizing unit 626.

Batch liquid PVD vacuum system 600 can be loaded and unloaded each time a PVD process runs. That process may include creating a vacuum in PVD vacuum chamber 618, introducing a raw liquid material into vaporizing unit 626, heating vaporizing unit 626 with resistive heating unit 672 (thereby creating a vaporized cloud of molecules (e.g., oleophobic material) that can coat electronic device components 606), returning PVD vacuum chamber 618 to ambient pressure, and removing coated electronic device components 606.

FIG. 6B shows a cross-sectional schematic view of batch liquid PVD system 600′ according to embodiments of the invention. Batch PVD system 600′ is identical to batch PVD system 600 except that batch liquid PVD system 600′ may include two or more vaporizing units 626. Similarly, system 600′ can include two or more resistive heating units 672 and tables 674 operable to heat and support two or more vaporizing units 626. Utilizing two or more vaporization units 626 within batch liquid PVD system 600′ may provide more consistent coating of electronic device components 606 by the coating molecules (e.g., the oleophobic ingredient) compared to batch liquid PVD system 600 wherein only one vaporization unit 626 is used.

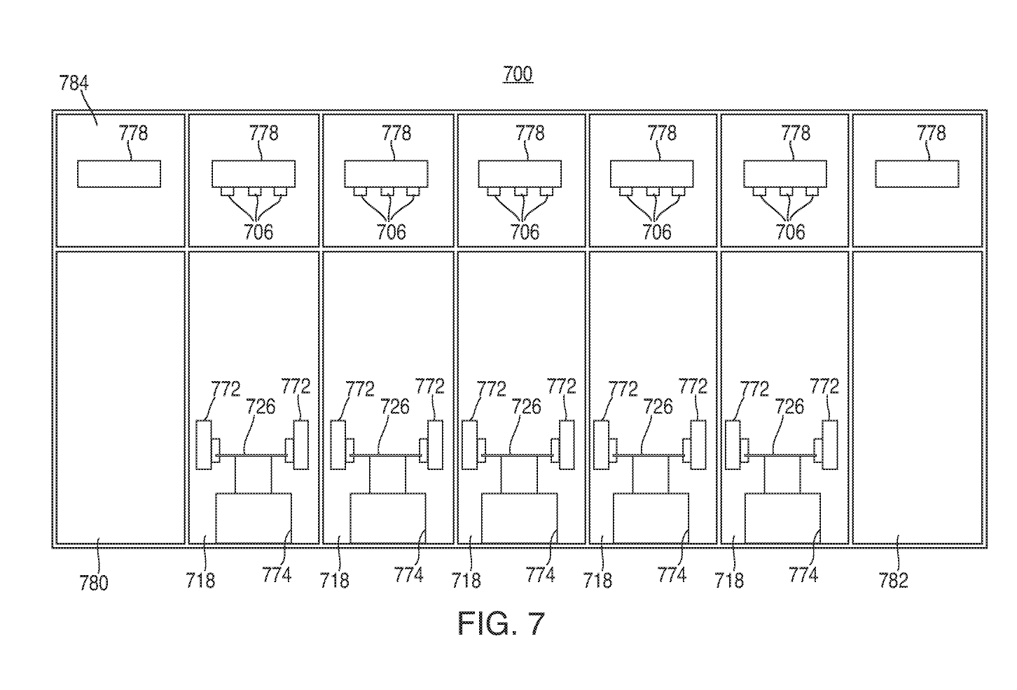

FIG. 7 is a schematic view of inline liquid PVD system 700 according to one embodiment of the invention. Inline liquid processing system 700 may include several vacuum chambers (e.g., five) 718 coupled together in a manner that maintains a constant pressure level for all of the chambers. Each vacuum chamber 718 contains rotating pallet 778 on which electronic device components 706 are mounted. In this embodiment, rotating pallets 778, whereon components 706 are mounted may be collected in a pre-exhaust chamber 782 after coating. The collection of rotating pallets 778 may be enabled by the use of conveyer 784 whereon rotating pallets 778 are mounted. Conveyer 784 may be operable to transport rotating pallets 778 between the chambers, including pre-evacuation chamber 780, vacuum chambers 718, and pre-exhaust chamber 782. When all rotating pallets 778 are collected, pre-exhaust chamber 782 can be returned to ambient pressure and opened. Electronic device components 706 may then be removed. Each vacuum chamber 718 may contain one or more sets of vaporizing unit 726, resistive heating unit 772, and table 774.

One advantage of inline liquid PVD system 700 is that an increase in throughput can be provided as compared to the previously described batch liquid PVD system (e.g., system 600 or 600′). For example, the vacuum level in vacuum chambers 718 may be maintained at all times. Thus, electronic device components 706 may be mounted onto rotating pallets 778 in pre-evacuation chamber 780 in ambient pressure. The pressure in pre-evacuation chamber 780 may then be reduced to match the pressure maintained within vacuum chambers 718 and pre-exhaust chamber 782. After the pressure is matched, conveyer 784 may transport a number of rotating pallets 778 into a number of vacuum chambers 718 for PVD processing (i.e., each vacuum chamber 718 should contain one rotating pallet 778). After processing, conveyer 784 can transport rotating pallets 778 into pre-exhaust chamber 782. Pre-exhaust chamber 782 may then be sealed off from vacuum chambers 718 whereupon the pressure in pre-exhaust chamber 782 can be matched to the ambient pressure. Pre-exhaust chamber 782 can then be opened, and electronic device components 706 removed from rotating pallets 778. In this way, many electronic device components can be coated in one process run, while the vacuum can be maintained in vacuum chambers 718 and time need not be taken to induce and exhaust the vacuum in every vacuum chamber 718 each time the PVD process is run.

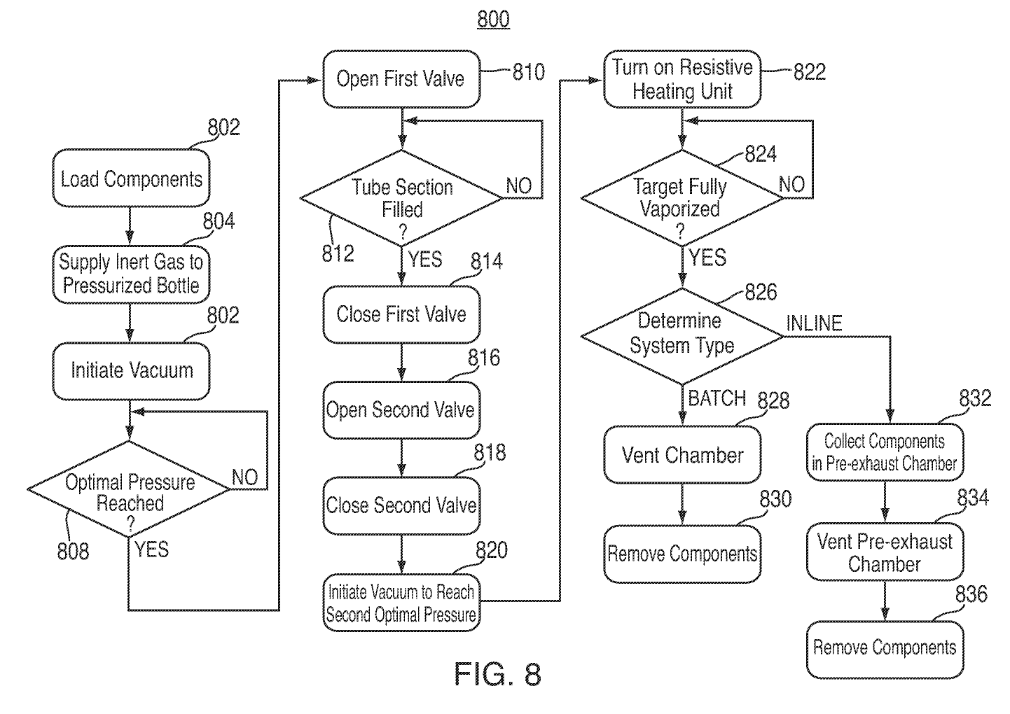

FIG. 8 is a flow chart of a process 800 for direct liquid vaporization to form oleophobic coatings. Reference to elements of FIGS. 5, 6A, 6B, and 7 will be made to simplify the description of process 800. The oleophobic coating may be suitable to coat electronic device components 506 (e.g., the windows 106 of electronic device 100 (as shown in FIG. 1 and described above). Process 800 begins with Step 802, where electronic device components 506 may be loaded into PVD vacuum chamber 518. In some embodiments, as many as 300 or more electronic device components 506 may be loaded into a PVD vacuum chamber 518. Next, inert gas 512 (e.g., argon or nitrogen) may be allowed to flow from gas source 516 into pressurized bottle 510 (Step 804). Then, vacuum pump 570 can be initiated to lower the pressure in PVD vacuum chamber 518 to an optimal level (Step 806).

A pressure sensor may be used to determine whether the optimal pressure has been reached within the PVD vacuum chamber 518 (Step 808). For example, the optimal pressure may be slightly above the vapor pressure of the dilutant in the raw liquid material (to prevent the dilutant from boiling violently upon introduction to the vaporizing unit). Once the optimal pressure within the PVD vacuum chamber is reached, first valve 530 may be opened to allow raw liquid material 508 to flow from pressurized bottle 510 through first tube section 522 into second tube section 534 (Step 810). Step 812 can be to determine whether the second tube is filled. In some embodiments, a flow meter 544, can be used to help accomplish this step determine when second tube section 534 is filled.

When second tube section 534 is filled, first valve 530 may be closed (Step 814). Second valve 536 may then be opened to allow raw liquid material 508 in second tube section 534 to flow into vaporizing unit 526 through supply tube 524 (Step 816). In some embodiments, the vacuum in PVD chamber 518 will be sufficient to ensure that all raw liquid material 508 in second tube section 534 is drawn into vaporizing unit 526. When second tube section 534 is empty, second valve 536 may be closed (Step 818).

Next, vacuum pump 570 may be initiated to lower the pressure in PVD vacuum chamber 518 to a second optimal pressure level (Step 820). For example, the second optimal pressure level may be sufficient to allow the dilutant in the raw liquid material 508 to fully vaporize and ensure that all molecules of the oleophobic ingredient will have a sufficiently long mean free path to reach and coat electronic device components 506. When step 820 is complete, only the oleophobic ingredient will remain in vaporizing unit 526.

When the second optimal pressure level is reached, vaporizing unit 526 can be heated (e.g., using resistive heating unit 572) to a temperature suitable to vaporize the oleophobic ingredient (Step 822). When the oleophobic ingredient is fully vaporized, (e.g., after a predetermined time has passed) resistive heating unit 572 may be turned off (Step 824). Then, the system type will be determined (e.g., batch or inline) using any suitable means (Step 826). For example, an additional logic element may be able to determine whether the system is a batch or inline system or the system type may be known in advance.

In some embodiments, a batch liquid physical vapor deposition system 600 is used, wherein a single vacuum chamber 618 is used to coat each set of electrical device components 606. In such embodiments, vacuum chamber 618 is returned to ambient pressure and opened (Step 828). Electrical device components 606 (now coated with an oleophobic coating) may then be removed (Step 830).

In other embodiments, an inline liquid physical vapor deposition system 700 is used, wherein several vacuum chambers 718 (e.g., five) are coupled together in a manner that maintains a constant pressure level for all of the chambers. Each vacuum chamber 718 contains at least one rotating flat pallet 778 on which electronic device components 706 are mounted. In these embodiments, rotating pallets 778, whereon components 706 are mounted, may be collected in pre-exhaust chamber 782 (Step 832). When all rotating pallets 778 are collected, pre-exhaust chamber 782 can be returned to ambient pressure and opened (Step 834). Coated electronic device components 706 may then be removed (Step 836).

The previously described embodiments are presented for purposed of illustration and not of limitation. It is understood that one or more features of an embodiment can be combined with one or more features of another embodiment to provide systems and/or methods without deviating from the spirit and scope of the invention. The present invention is limited only by the claims that follow.

What is claimed is:

1. A vaporizing unit for physical vapor deposition, comprising:
a vessel operable to receive a raw liquid material;
a cover coupled to the vessel comprising:
an aperture through which the raw liquid material may be inserted into the vessel; and
a plurality of holes operative to allow the target material to escape when the target material is in vapor form; and
a supply tube coupled to the aperture, the tube operable to direct the target material in liquid form into the vessel.

2. The vaporizing unit of claim 1 further comprising tabs operable to couple to a resistive heating unit.

3. The vaporizing unit of claim 1, wherein the raw liquid material is comprised of:
an oleophobic ingredient; and
a dilutant.

4. The vaporizing unit of claim 2 wherein the vessel and cover are comprised of molybdenum.

5. The vaporizing unit of claim 2 wherein the supply tube is comprised of a heat-resistant carbon material.

6. The vaporizing unit of claim 2 wherein the supply tube is comprised of a ceramic material.

7. A physical vapor deposition system comprising:
a pressurized bottle for storing a raw liquid material in liquid form;
a pressure source for supplying back pressure to the pressurized bottle;
a tube section fluidly coupled to the pressurized bottle;
a least one valve selectively allowing the raw liquid material to flow through the tube section; and
a vessel coupled to first tube and operable to receive the target material flowing from the pressurized bottle.

8. The physical vapor deposition system of claim 7, wherein the pressure source is a gas source.

9. The physical vapor deposition system of claim 7, further comprising a physical vapor deposition vacuum chamber.

10. The physical vapor deposition system of claim 7, wherein the raw liquid material is comprised of:
an oleophobic ingredient; and
a dilutant.

11. The physical vapor deposition system of claim 9, wherein the pressurized bottle is stored in a refrigerated environment.

12. The physical vapor deposition system of claim 9, wherein the at least one valve is fluidly coupled to a liquid supply system comprising:
a second tube section, wherein a first end is fluidly coupled to the at least one valve; and
a second valve, a first side of which is coupled to a second end of the second tube section and a second side of which is fluidly coupled to the supply tube.

13. The physical vapor deposition system of claim 9, wherein the at least one valve is fluidly coupled to a liquid supply system comprising:
at least one micro syringe fluidly coupled to the pressurized bottle and at least one supply syringe; and
at least one supply syringe fluidly coupled to at least one micro syringe and the vaporizing unit.

14. The physical vapor deposition system of claim 13, wherein the gas source is operable to provide pressure to the at least one micro syringe and the at least one supply syringe.

15. The physical vapor deposition system of claim 9, wherein the physical vapor deposition system is a batch liquid physical vapor deposition system.

16. The physical vapor deposition system of claim 9, wherein the physical vapor deposition system is an inline liquid physical vapor deposition system.

17. The physical vapor deposition system of claim 9, further comprising a logic element operable to determine whether the physical vapor deposition system is a batch liquid physical vapor deposition system or an inline liquid physical vapor deposition system.

18. The physical vapor deposition system of claim 9, wherein whether the physical vapor deposition system is a batch liquid physical vapor deposition system or an inline liquid physical vapor deposition system is known in advance.

19. A method for depositing a coating on a surface of a component, comprising:
placing at least one component within a vacuum chamber, wherein a surface of each of the at least one component is exposed;
selecting a particular amount of a raw liquid material, wherein the particular amount is selected based on the number of at least one components placed within the vacuum chamber;
inserting a shot of the raw liquid material in a vaporizing unit placed within the vacuum chamber; and
heating the vaporizing unit to vaporize the raw liquid material, wherein an ingredient of the vaporized raw liquid material is deposited on the surface of the at least one component.

20. The method of claim 19, wherein the vacuum chamber is held at a first optimal pressure prior to inserting the shot of raw material liquid into the vaporizing unit.

21. The method of claim 20, wherein the method further comprises reducing the pressure in the vacuum chamber to a second optimal level after inserting the shot of raw material liquid into the vaporizing unit and before heating the vaporizing unit to vaporize the raw liquid material.

22. The method of claim 19, further comprising:
changing the pressurized bottle when it is empty; and
venting the system with an air vent.
